(19) United States
(12) Patent Application Publication
(10) Pub. No.: US 2011/0315191 A1
(43) Pub. Date: Dec. 29, 2011

(54) METHOD FOR MANUFACTURING SEMICONDUCTOR DEVICE

(75) Inventors: Hirotaki Takanashi, Chigasaki-shi (JP); Yuko Taguchi, Chigasaki-shi (JP); Michihiro Takayama, Chigasaki-shi (JP); Hiroto Uchida, Chigasaki-shi (JP)

(73) Assignee: ULVAC, INC., Chigasaki-shi (JP)

(21) Appl. No.: 13/254,524

(22) PCT Filed: Mar. 5, 2010
(86) PCT No.: PCT/JP2010/001565

§ 371 Date: Sep. 2, 2011

(30) Foreign Application Priority Data
Mar. 6, 2009 (JP) P2009-054253

(51) Int. Cl. H01L 31/042; H01L 31/18

(52) U.S. Cl. 136/244; 438/64; 257/E31.117

(57) ABSTRACT

A frameless solar cell panel includes: a stacked body (10) that has an end portion (10a) and in which a first substrate (2), a power generating section (3), a sealing layer (4), and a back sheet (5) or a second substrate (6) are sequentially stacked; and a silicone sealant member (11) that is disposed in the end portion (10a) of the stacked body (10).

### CROSS-REFERENCE TO RELATED APPLICATION

This is the U.S. National Phase Application under 35 U.S.C. §371 of International Patent Application No. PCT/JP2010/001565 filed Mar. 5, 2010, which designated the United States and was published in a language other than English, which claims the benefit of Japanese Patent Application No. 2009-054253, filed Mar. 6, 2009, both of them are incorporated by reference herein. The International Application was published in Japanese on Sep. 10, 2010 as WO2010/100948 A1 under PCT Article 21(2).

### TECHNICAL FIELD

The present invention relates to a frameless solar cell panel and a method of manufacturing a frameless solar cell panel.

### BACKGROUND ART

In recent years, solar cells have attracted more attention as an alternative energy source.

There is a demand to reduce the cost of the solar cells.

Particularly, solar cells using a thin-film semiconductor material such as amorphous silicon have attracted attention.

FIG. 8 is a cross-sectional view illustrating a conventional amorphous-silicon solar cell panel (for example, Japanese Unexamined Patent Application, First Publication No. H9-331079).

As shown in FIG. 8, a solar cell panel 112 includes a glass substrate 100 and a solar cell layer (power generating layer) 102 formed on the back surface of the glass substrate 100 out of amorphous silicon.

In this configuration, solar light incident on the glass substrate 100 is received by the solar cell layer 102.

An adhesive layer 104 formed of ethylene vinyl acetate (EVA) is disposed on the solar cell layer 102.

The adhesive layer 104 serves to protect the solar cell layer 102.

A Tedlar film 106 is formed on the adhesive layer 104 by back coating.

A frame 108 covering part of the surface of the glass substrate 100 and part of the Tedlar film 106 is disposed on the end face of the glass substrate 100.

An adhesive 110 formed of butyl rubber is disposed between the end face of the glass substrate 100 and the frame 108.

In this configuration, the frame 108 has a recessed portion and a stacked body including the glass substrate 100, the solar cell layer 102, the adhesive layer 104, and the Tedlar film 106 is inserted into the recessed portion with the adhesive 110 interposed therebetween.

In the solar cell panel 112 having this structure, water is prevented from infiltrating from the end face by the adhesive 110 and thus the rigidity of the solar cell panel 112 is guaranteed by the frame 108.

To achieve a decrease in the weight of the solar cell panel and to reduce the manufacturing cost thereof, the implementation of a frameless solar cell panel is anticipated.

However, when the solar cell panel 112 employs a frameless structure, the resin such as the EVA resin is exposed to the outside of the solar cell panel 112 from the space between the Tedlar film 106 and the glass substrate 100.

In this structure, moisture can easily infiltrate through the exposed portion.

The EVA resin is poor in terms of weather resistance and the EVA resin deteriorates when it is exposed to the solar light or wind and rain outdoors for a long time.

Accordingly, moisture infiltrates greatly from the deteriorated portion of the EVA resin.

In this case, solar cell elements adjacent to each other are short-circuited, thereby reducing the performance of the solar cell panel.

Therefore, there is a need to improve the weather resistance in the frameless solar cell panel.

Although a problem in a solar cell is mentioned above using the amorphous-silicon solar cell panel as an example, this problem is not limited to the amorphous-silicon solar cell panel.

This problem is common to other solar cell panels of a solar cell using monocrystalline silicon, a dye-sensitized solar cell, or the like.

### DISCLOSURE OF INVENTION

### Problems to be Solved by the Invention

The invention is made in consideration of the above-mentioned problem, and has a first object to provide a frameless solar cell module that can guarantee resistance to ultraviolet or moisture and that has a frameless structure.

The invention has a second object to provide a method of manufacturing a frameless solar cell module, in which a frameless solar cell module that can guarantee resistance to ultraviolet or moisture and that has a frameless structure can be manufactured by the use of a simple coating method.

### Means for Solving the Problems

According to a first aspect of the invention, there is provided a frameless solar cell panel including: a stacked body having an end portion and in which a first substrate, a power generating section, a sealing layer, and a back sheet or a second substrate are sequentially stacked; and a silicone sealant member that is disposed in the end portion of the stacked body.

In the frameless solar cell panel according to the first aspect of the invention, it is preferable that the first substrate include a first outer surface and a first outer edge portion located on the first outer surface, the back sheet or the second substrate include a second outer surface and a second outer edge portion located on the second outer surface, the silicone sealant member cover at least the end portion of the stacked body, the first outer edge portion of the first substrate, and the second outer edge portion of the back sheet or the second substrate, and the silicone sealant member be formed substantially in a U-shape in a cross-sectional view of the stacked body.

In the frameless solar cell panel according to the first aspect of the invention, it is preferable that the first substrate include a first outer surface and a first outer edge portion located on the first outer surface, the silicone sealant member cover at least the end portion of the stacked body and the first outer edge portion of the first substrate, and the silicone sealant member be formed substantially in an L-shape in a cross-sectional view of the stacked body.

In the frameless solar cell panel according to the first aspect of the invention, it is preferable that an adhesive layer formed of butyl rubber be disposed between the silicone sealant member and the stacked body.

In the frameless solar cell panel according to the first aspect of the invention, it is preferable that the silicone sealant member further include a metallic member disposed in the end portion of the stacked body, and the silicone sealant member be disposed in the end portion so as to cover the metallic member.

In the frameless solar cell panel according to the first aspect of the invention, it is preferable that the sealing layer contain one of a silane-modified polyolefin, an ethylene-unsaturated carboxylic acid copolymer, ionomers thereof, and ethylene-unsaturated carboxylic ester copolymer.

In the frameless solar cell panel according to the first aspect of the invention, it is preferable that the sealing layer contain one of ethylene vinyl acetate and polyvinyl butyral.

According to a second aspect of the invention, there is provided a method of manufacturing a frameless solar cell panel, including: preparing a stacked body that has an end portion and in which a first substrate, a power generating section, a sealing layer, and a back sheet or a second substrate are sequentially stacked, and coating the end portion of the stacked body with a silicone sealant material (first process); and curing the silicone sealant material (second process).

In the method of manufacturing a frameless solar cell panel according to the second aspect of the invention, it is preferable that the curing of the silicone sealant material be performed after the coating with the silicone sealant material is performed.

In the method of manufacturing a frameless solar cell panel according to the second aspect of the invention, it is preferable that the curing of the silicone sealant material be performed while the coating with the silicone sealant material is being performed.

In the method of manufacturing a frameless solar cell panel according to the second aspect of the invention, it is preferable that high-humidity air be blown onto the silicone sealant material at the time of curing the silicone sealant material.

In the method of manufacturing a frameless solar cell panel according to the second aspect of the invention, it is preferable that a metallic member be disposed in the end portion of the stacked body, and the end portion be coated with the silicone sealant material so as to cover the metallic member.

In the method of manufacturing a frameless solar cell panel according to the second aspect of the invention, it is preferable that the sealing layer contain one of a silane-modified polyolefin, an ethylene-unsaturated carboxylic acid copolymer, ionomers thereof, and an ethylene-unsaturated carboxylic ester copolymer.

In the method of manufacturing a frameless solar cell panel according to the second aspect of the invention, it is preferable that the sealing layer contain one of ethylene vinyl acetate and polyvinyl butyral.

### Effects of the Invention

According to the first aspect of the invention, the silicone sealant member is disposed in the end portion of the stacked body in which the first substrate, the power generating section, the sealing layer, and the back sheet or the second substrate are sequentially stacked.

In this configuration, the weather resistance to ultraviolet (UV) light or moisture is guaranteed and it is thus possible to achieve sufficient rigidity to protect the stacked body.

According to the invention, it is possible to implement a frameless structure, thereby providing a frameless solar cell panel.

According to the second aspect of the invention, the end portion of the stacked body in which the first substrate, the power generating section, the sealing layer, and the back sheet or the second substrate are sequentially stacked is coated with the silicone sealant material.

In addition, the silicone sealant material is cured.

In this method, the weather resistance to ultraviolet (UV) light or moisture is guaranteed and it is thus possible to implement a solar cell panel that can achieve sufficient rigidity to protect the stacked body.

Accordingly, the invention can provide a method of manufacturing a frameless solar cell panel that can protect an end portion of a stacked body by the use of a simple coating method and that has a frameless structure.

### BRIEF DESCRIPTION OF THE DRAWINGS

FIG. 1 is a cross-sectional view schematically illustrating a frameless solar cell panel according to a first embodiment of the invention.

FIG. 2 is a cross-sectional view schematically illustrating an amorphous-silicon solar cell included in the solar cell panel according to the first embodiment.

FIG. 3 is a cross-sectional view schematically illustrating a frameless solar cell panel according to a second embodiment of the invention.

FIG. 4 is a cross-sectional view schematically illustrating a frameless solar cell panel according to a third embodiment of the invention.

FIG. 5 is a cross-sectional view schematically illustrating a frameless solar cell panel according to a fourth embodiment of the invention.

FIG. 6 is a cross-sectional view schematically illustrating a frameless solar cell panel according to a fifth embodiment of the invention.

FIG. 7A is a cross-sectional view schematically illustrating a frameless solar cell panel according to a sixth embodiment of the invention.

FIG. 7B is a cross-sectional view schematically illustrating the frameless solar cell panel according to the sixth embodiment of the invention and is an enlarged view partially illustrating the frameless solar cell panel shown in FIG. 7A.

FIG. 8 is a cross-sectional view schematically illustrating a conventional solar cell panel.

### EMBODIMENTS FOR CARRYING OUT THE INVENTION

Hereinafter, frameless solar cell panels and methods of manufacturing the frameless solar cell panels according to embodiments of the invention will be described with reference to the accompanying drawings.

In the drawings referred to in the following description, the sizes and scales of elements are appropriately set to be different from the actual ones so as to facilitate recognition of the elements from the drawings.

In the following description, an amorphous-silicon solar cell panel is given as on example, but the invention is not limited to this.

For example, the invention can be applied to other types of solar cell panels such as a monocrystalline silicon solar cell and a dye-sensitized solar cell.

### First Embodiment

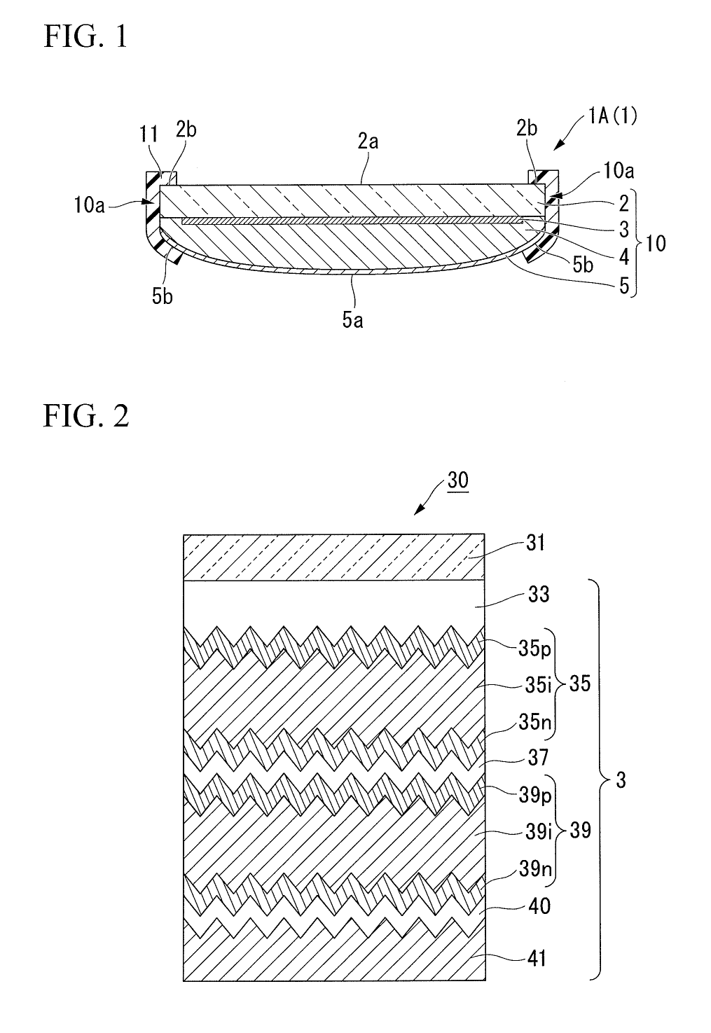

FIG. 1 is a cross-sectional view schematically illustrating a frameless solar cell panel according to a first embodiment of the invention.

The frameless solar cell panel 1A (1) according to the first embodiment includes a stacked body 10 and a silicone sealant member 11.

In the stacked body 10, a transparent first substrate 2, a power generating section 3, a sealing layer 4, and a back sheet 5 are sequentially stacked.

The silicone sealant member 11 is disposed on a side surface 10a (end portion) of the stacked body 10.

In the frameless solar cell panel 1A (1) according to the first embodiment, since the silicone sealant member 11 is disposed on the side surface 10a of the stacked body 10, resistance to ultraviolet (UV) or moisture is guaranteed and it is thus possible to achieve the rigidity sufficient to protect the stacked body 10.

Accordingly, in the first embodiment, it is possible to implement a solar cell panel having a frameless structure.

Ethylene vinyl acetate, polyvinyl butyral, or the like can be used as the material of the sealing layer 4.

It is preferable that a highly hydrophobic resin such as a silane-modified polyolefin, an ethylene-unsaturated carboxylic acid copolymer, ionomers thereof, and an ethylene-unsaturated carboxylic ester copolymer having a lower moisture transmitting property is used.

In the frameless solar cell panel 1A (1), a solar cell constituting the power generating section 3 is, for example, an amorphous-silicon solar cell.

FIG. 2 is a cross-sectional view schematically illustrating an amorphous-silicon solar cell 30.

The solar cell 30 has a structure in which a glass substrate 31, an upper electrode 33, a top cell 35, an intermediate electrode 37, a bottom cell 39, a buffer layer 40, and a rear electrode 41 are stacked.

The glass substrate 31 constitutes the surface of the frameless solar cell panel 1A (1).

The upper electrode 33 is disposed on the glass substrate 31 and is formed of a zinc-oxide transparent conductive film.

The top cell 35 is formed of amorphous silicon.

The intermediate electrode 37 is disposed between the top cell 35 and the bottom cell 39 and is formed of a transparent conductive film.

The bottom cell 39 is formed of microcrystalline silicon.

The buffer layer 40 is formed of a transparent conductive film.

The rear electrode 41 is formed of a metal film.

The glass substrate 31 corresponds to the transparent first substrate 2.

The upper electrode 33, the top cell 35, the intermediate electrode 37, the bottom cell 39, the buffer layer 40, and the rear electrode 41 correspond to the power generating section 3.

The top cell 35 has a three-layered structure of a p layer (35p), an i layer (35i), and an n layer (35n).

The i layer (35i) is formed of amorphous silicon.

The bottom cell 39 has a three-layered structure of a p layer (39p), an i layer (39i), and an n layer (39n), similarly to the top cell 35.

The i layer (39i) is formed of microcrystalline silicon.

In the solar cell 30 having this structure, solar light incident on the glass substrate 31 passes through the upper electrode 33, the top cell 35 (p-i-n layers), the bottom cell 39 (p-i-n layers), and the buffer layer 40 and is reflected by the rear electrode 41.

When energy particles such as photons included in solar light reach the i layer, electrons and holes are generated due to a photovoltaic effect, the generated electrons move to the n layer, and the generated holes move to the p layer.

The electrons and holes generated due to the photovoltaic effect are extracted by the upper electrode 33 and the rear electrode 41 and optical energy is converted into electric energy.

In order to improve the conversion efficiency of optical energy, the solar cell employs a structure for reflecting solar light in the rear electrode 41 or employs a structure called a texture structure disposed in the upper electrode 31.

In the texture structure, it is possible to achieve a prism effect elongating an optical path of the solar light and a light trapping effect.

The buffer layer 40 is disposed to prevent the metal film used in the rear electrode 41 from diffusing or the like.

In the frameless solar cell panel 1A (1) according to the first embodiment, the silicone sealant member 11 is disposed on the side surface 10a of the stacked body 10 in which the first substrate 2, the power generating section 3, the sealing layer 4, and the back sheet 5 are sequentially stacked.

The sealing layer 4 is disposed to cover the power generating section 3 disposed on the first substrate 2.

Accordingly, it is possible to protect the power generating section 3 from severe external environments in which temperature variation, humidity, impacts, or the like occur.

Accordingly, it is possible to implement the frameless solar cell panel 1A (1) which is excellent in humidity resistance and weather resistance.

A highly hydrophobic resin (such as a silane-modified polyolefin, an ethylene-unsaturated carboxylic acid copolymer, ionomers thereof, and an ethylene-unsaturated carboxylic ester copolymer) is suitably used as the material of the sealing layer 4.

The highly hydrophobic resin is a material having humidity resistance, weather resistance, cold resistance, impact resistance, or the like and being a nicely balanced in above resistances for a solar cell.

The material of the silicone sealant member 11 is not particularly limited and for example, “Shin-Etsu Silicone” RTV rubber made by Shin-Etsu Chemical Co., Ltd. can be used.

Since the RTV (Room Temperature Vulcanizable) rubber is low in cost and is easily cured, it can be suitably used as a sealant material.

Since the RTV rubber has a characteristic that the volume does not vary with curing, it is possible to suppress a stress from being applied to the edge portion of the stacked body 10 by the curing.

In the example shown in FIG. 1, the stacked body 10 has the side surface 10a.

The first substrate 2 includes an outer surface 2a (the first outer surface) and an outer edge portion 2b (the first outer edge portion) located on the outer surface 2a.

The back sheet 5 includes an outer surface 5a (the second outer surface) and an outer edge portion 5b (the second outer edge portion) located on the outer surface 5a.

The silicone sealant member 11 covers at least the side surface 10a, the outer edge portion 2b, and the outer edge portion 5b.

The silicone sealant member 11 is formed substantially in a U-shape in a cross-sectional view of the stacked body 10.

Since the silicone sealant member 11 is formed substantially in a U-shape, it is possible to satisfactorily prevent moisture or the like from infiltrating into the stacked body 10 from the side surface 10a of the stacked body 10 and thus to guarantee weather resistance, thereby satisfactorily protecting the stacked body 10.

The silicone sealant member 11 is not limited to the example shown in FIG. 1, as long as it covers the side surface 10a of the stacked body 10 and the corners (the vicinity of the outer edge portion 2b) of the substrate 2 on which light is incident.

A glass substrate is typically used as the substrate (the first substrate 2 in FIG. 1) on which light is incident.

Accordingly, in order to prevent an operator from coming in contact with the corners of the first substrate 2 at the time of carrying the frameless solar cell panel 1A (1), or in order to prevent the frameless solar cell panel 1A (1) from being destroyed by impact, it is preferable that the corners of the first substrate 2 are covered with the silicone sealant member.

### Second Embodiment

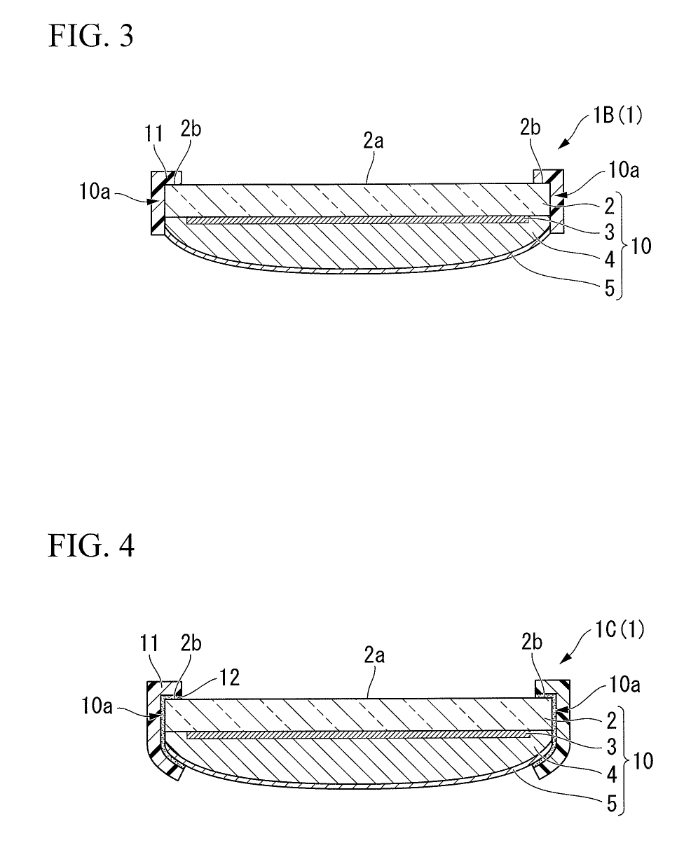

In FIG. 3, the same elements as described in the first embodiment are referenced by the same reference numerals and signs and the description thereof is not repeated or is made in brief.

In a frameless solar cell panel 1B (1) shown in FIG. 3, the silicone sealant member 11 covers at least the side surface 10a of the stacked body 10 and the outer edge portion 2b on the outer surface 2a of the first substrate 2.

The silicone sealant member 11 is formed substantially in an L-shape in a cross-sectional view of the stacked body 10.

In this configuration, it is possible to achieve the same advantages as described in the first embodiment.

### Third Embodiment

In FIG. 4, the same elements as described in the first embodiment are referenced by the same reference numerals and signs and the description thereof is not repeated or is made in brief.

In the frameless solar cell panel 1C (1) shown in FIG. 4, an adhesive layer 12 formed of butyl rubber is disposed between the silicone sealant member 11 and the stacked body 10.

The butyl rubber is excellent in vapor permeation resistance.

Since the adhesive layer 12 is disposed, it is possible to satisfactorily prevent moisture or the like from infiltrating into the stacked body 10 from the side surface 10a of the stacked body 10.

Accordingly, it is possible to implement the frameless solar cell panel 1C (1) that is superior in humidity resistance.

(Manufacturing Method)

A method of manufacturing the above-mentioned frameless solar cell panel will be described below.

In the method of manufacturing a frameless solar cell panel, the stacked body 10 in which the transparent first substrate 2, the power generating section 3, the sealing layer 4, and the back sheet 5 are sequentially stacked is prepared and the side surface 10a of the stacked body 10 is coated with the silicone sealant material 11 (first process) and the silicone sealant material 11 is cured (second process).

In this manufacturing method, the side surface 10a of the stacked body 10 is coated with the silicone sealant material 11 and the silicone sealant material 11 is cured.

Accordingly, it is possible to implement a solar cell panel that can guarantee the weather resistance to ultraviolet (UV) light or moisture and that has rigidity sufficient to protect the stacked body 10.

Accordingly, in this manufacturing method, it is possible to manufacture a frameless solar cell panel 1 in which the side surface 10a of the stacked body 10 can be protected using a simple coating method and in which a frameless structure is implemented.

(1) First, the first substrate 2, the power generating section 3, the sealing layer 4, and the back sheet 5 are sequentially stacked to form the stacked body 10.

The side surface 10a of the stacked body 10 is coated with the silicone sealant material 11 (first process).

The silicone sealant material 11 is applied to a portion corresponding to the side surface 10a (end portion) of the stacked body 10.

For example, “Shin-Etsu Silicone” RTV rubber made by Shin-Etsu Chemical Co., Ltd. may be used as the silicone sealant material 11.

Any of a one-component condensation reaction rubber, a one-component addition reaction rubber, and a two-component addition reaction rubber can be used for the RTV rubber.

Particularly, the one-component RTV rubber is excellent in workability and is also excellent in wettability with the glass substrate, thermal resistance, and the like.

A coating method with the silicone sealant material 11 is not particularly limited, and methods such as a dispensing method and a screen printing method can be used.

Particularly, it is preferable that the screen printing method capable of performing the coating work well is used.

A method (single coating method) of forming the silicone sealant material 11 by a single coating process may be employed as the coating method with the silicone sealant material 11.

The silicone sealant material is first applied to form a first film, the silicone sealant material is applied onto the first film to form a second film, whereby the silicone sealant material 11 having a two-layered structure may be formed (double coating, recoating).

The thickness of the coating film is not particularly limited.

For example, in the case of the single coating, it is preferable that the coating film is formed with a thickness of 0.1 to 5 mm.

In the case of double coating (recoating), it is preferable that the coating film is formed with a thickness of 0.1 to 10 mm in total.

The side surface 10a of the stacked body 10 may be coated with an adhesive formed of butyl rubber before the side surface 10a of the stacked body 10 is coated with the silicone sealant material 11.

(2) Then, the silicone sealant material 11 applied to the side surface 10a of the stacked body 10 is cured (the second process).

At this time, it is preferable that the silicone sealant material 11 is cured while blowing high-humidity air thereto.

Accordingly, the curing speed of the silicone sealant material 11 increases, therefore preventing drooping thereof.

When the one-component condensation reaction rubber is used as the silicone sealant material 11, the curing time is shortened by curing the silicone sealant material in an atmosphere of high temperature and high humidity.

Accordingly, it is preferable that the silicone sealant material 11 is cured in the atmosphere of high temperature and high humidity.

It is preferable that the temperature be 20° C. to 50° C. and the humidity be 50% RH to 100% RH.

When the one-component addition reaction rubber is used as the silicone sealant material 11, the curing time is shortened by curing the silicone sealant material in the atmosphere with high temperature.

Accordingly, it is preferable that the silicone sealant material 11 is cured in the atmosphere with a high temperature.

It is preferable that the temperature be 80° C. to 150° C.

When the two-component addition reaction type is used as the silicone sealant material 11, the curing time is shortened by curing the silicone sealant material in the atmosphere with a high temperature.

Accordingly, it is preferable that the silicone sealant material 11 is cured in the atmosphere with a high temperature.

It is preferable that the temperature be 40° C. to 80° C.

Although it is described above that the first process and the second process are sequentially performed, the first process and the second process may be simultaneously performed on the same substrate (the stacked body 10).

In this case, it is preferable that an apparatus in which a coater serving to coat a workpiece with the silicone sealant material 11 be equipped with a curing apparatus serving to cure the silicone sealant material 11 can be used.

By using this apparatus, the applied silicone sealant material 11 may be sequentially cured while coating the side surface 10a of the stacked body 10 with the silicone sealant material 11.

### Fourth Embodiment

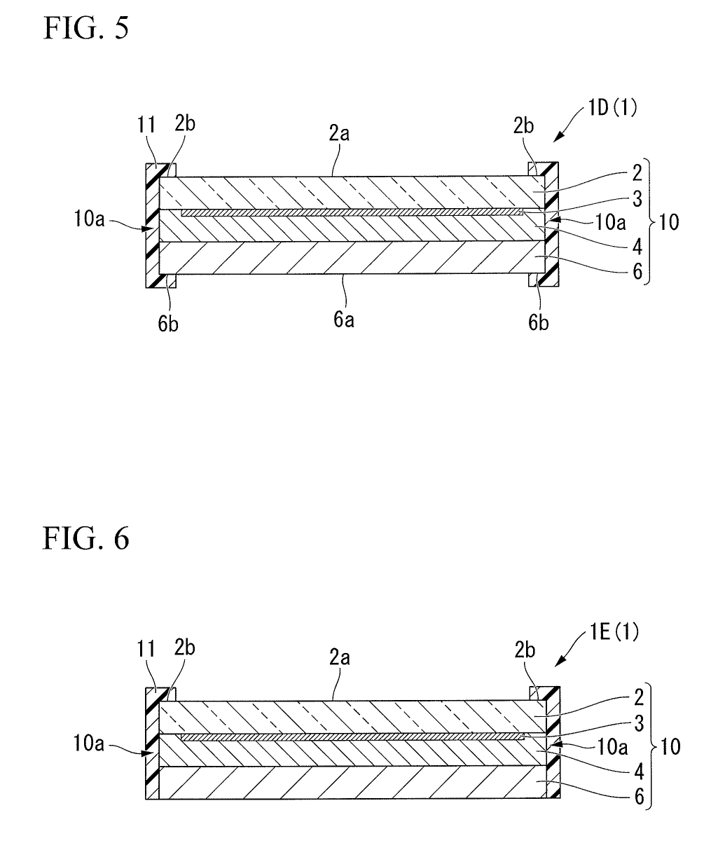

In FIG. 5, the same elements as described in the first embodiment are referenced by the same reference numerals and signs and the description thereof is not repeated or is made in brief.

FIG. 5 is a cross-sectional view illustrating a frameless solar cell panel 1D (1) according to a fourth embodiment of the invention.

In the frameless solar cell panel 1D (1) according to the fourth embodiment, a second substrate 6 is disposed instead of the back sheet.

That is, the transparent first substrate 2, the power generating section 3, the sealing layer 4, and the second substrate 6 are sequentially stacked in the stacked body 10.

For example, a glass substrate is used as the material of the second substrate 6.

Since the second substrate 6 is provided, it is possible to implement the frameless solar cell panel 1D (1) which is more excellent in rigidity and impact resistance.

In the example shown in FIG. 5, the stacked body 10 includes the side surface 10a.

The first substrate 2 includes the outer surface 2a (the first outer surface) and the outer edge portion 2b (the first outer edge portion) located on the outer surface 2a.

The second substrate 6 includes an outer surface 6a (the second outer surface) and an outer edge portion 6b (the second outer edge portion) located on the outer surface 6a.

The silicone sealant member 11 covers at least the side surface 10a, the outer edge portion 2b, and the outer edge portion 6b.

The silicone sealant member 11 is formed substantially in a U-shape in a cross-sectional view of the stacked body 10.

The silicone sealant member 11 is not limited to the example shown in FIG. 5, as long as it covers the side surface 10a of the stacked body 10 and the corners (the vicinity of the outer edge portion 2b) of the substrate 2 on which light is incident.

By employing this configuration, it is possible to achieve the same advantages as described in the first embodiment.

### Fifth Embodiment

In FIG. 6, the same elements as described in the first embodiment are referenced by the same reference numerals and signs and the description thereof is not repeated or is made in brief.

In a frameless solar cell panel 1E (1) shown in FIG. 6, the silicone sealant member 11 covers at least the side surface 10a of the stacked body 10 and the outer edge portion 2b of the outer surface 2a of the first substrate 2.

The silicone sealant member 11 is formed substantially in an L-shape in a cross-sectional view of the stacked body 10.

By employing this configuration, it is possible to achieve the same advantages as described in the first embodiment.

### Sixth Embodiment

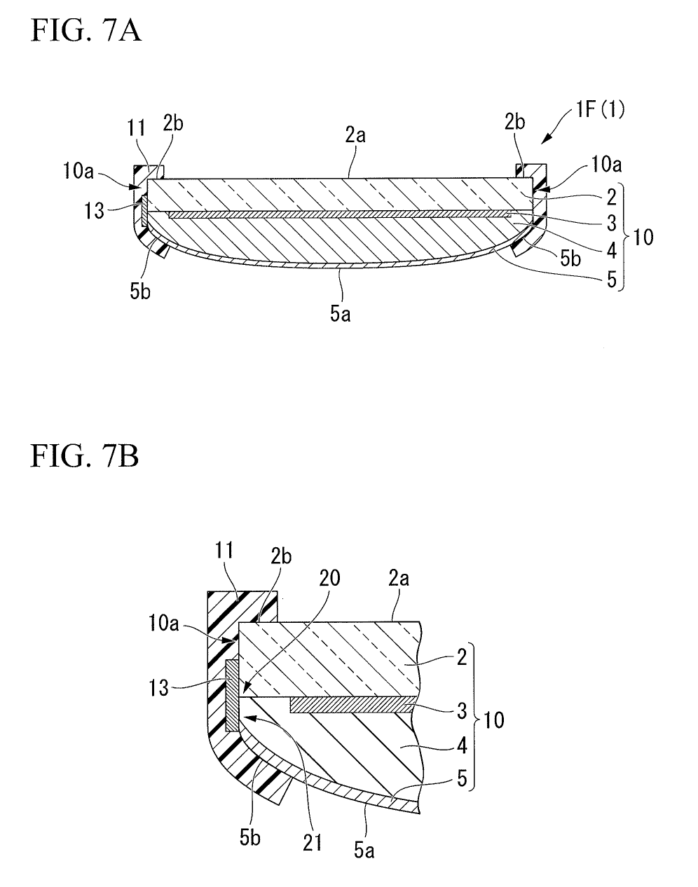

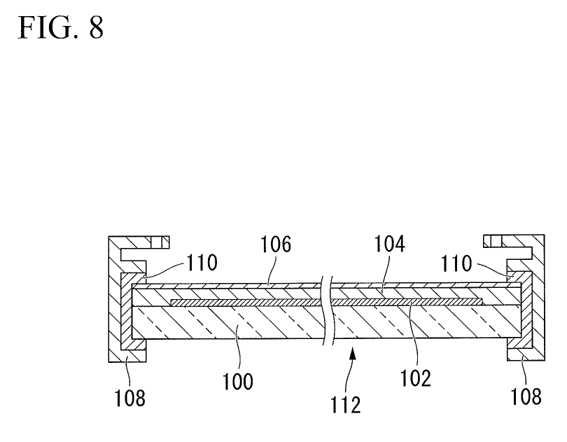

In FIGS. 7A and 7B, the same elements as described in the first embodiment are referenced by the same reference numerals and signs and the description thereof is not repeated or is made in brief.

In a frameless solar cell panel 1F (1) shown in FIGS. 7A and 7B, a metallic member is disposed between the silicone sealant member 11 and the side surface 10a of the stacked body 10.

In the sixth embodiment, an aluminum tape 13 formed of aluminum is used as the metallic member.

The aluminum tape 13 has an adhesive surface onto which an adhesive is applied.

Since the adhesive surface of the aluminum tape 13 comes in contact with the side surface 10a of the stacked body 10, the aluminum tape 13 adheres to the side surface 10a.

Accordingly, the side surface 10a of the stacked body 10 is covered with the aluminum tape 13.

Specifically, the aluminum tape 13 is disposed to cover a first junction 20 between the first substrate 2 and the sealing layer 4 and to cover a second junction 21 between the sealing layer 4 and the back sheet 5.

Accordingly, it is possible to prevent moisture from infiltrating into the stacked body 10 from the first junction 20 and the second junction 21.

The silicone sealant member 11 is disposed on the side surface 10a so as to cover the aluminum tape 13.

The silicone sealant member 11 covers at least the side surface 10a, the outer edge portion 2b, and the outer edge portion 5b as described in the first embodiment.

The silicone sealant member 11 is formed substantially in a U-shape in a cross-sectional view of the stacked body 10.

In this way, in a sealing structure in which the aluminum tape 13 and the silicone sealant member 11 are disposed on the side surface 10a, it is possible to further achieve an advantage resulting from the aluminum tape 13, as well as to achieve the advantages which result from the silicone sealant member 11 as described in the first embodiment.

That is, it is possible to satisfactorily prevent the moisture or the like from infiltrating into the stacked body 10 from the side surface 10a of the stacked body 10 and to guarantee the weather resistance, therefore satisfactorily protecting the stacked body 10.

The aluminum tape 13 is a flexible metal tape.

Accordingly, the aluminum tape 13 can be uniformly disposed on the side surface 10a along the side surface 10a of the stacked body 10 and it is thus possible to prevent a space from being formed between the aluminum tape 13 and the side surface 10a.

As a result, it is possible to prevent the moisture or the like from infiltrating into the stacked body 10 through the clearance.

While the structure employing the aluminum tape 13 as the metallic member is described in the sixth embodiment, the invention is not limited to this structure.

A metal tape formed of a metal other than aluminum may be employed instead of the aluminum tape 13.

A thin metal film (metallic member) may be formed on the side surface 10a using a known film forming method.

For example, by coating the side surface 10a of the stacked body 10 with a paste containing metal particles, a metallic member may be formed on the side surface 10a.

As shown in FIGS. 3 and 6, the metallic member may be formed on the side surface 10a even in the structure in which the silicone sealant member 11 is formed substantially in an L-shape in a cross-sectional view of the stacked body 10.

As shown in FIG. 4, the metallic member may be formed on the side surface 10a even in the structure in which the adhesive layer 12 is disposed between the silicone sealant member 11 and the stacked body 10.

In this case, the adhesive layer 12 is disposed to cover the metallic member and the silicone sealant member 11 is disposed to cover the adhesive layer 12.

As shown in FIGS. 5 and 6, the metallic member may be formed on the side surface 10a even in the stacked body 10 including the second substrate 6.

In this case, the metallic member is disposed to cover the junction between the sealing layer 4 and the second substrate 6.

While the frameless solar cell panel according to the invention and the manufacturing method thereof are described above, the technical scope of the invention is not limited to the above-mentioned embodiments, but the invention may be modified in various forms without departing from the concept of the invention.

### INDUSTRIAL APPLICABILITY

The invention can be widely applied to a frameless solar cell panel and a manufacturing method thereof.

What is claimed is:

1. A frameless solar cell panel comprising:
a stacked body having an end portion and in which a first substrate, a power generating section, a sealing layer, and a back sheet or a second substrate are sequentially stacked; and
a silicone sealant member that is disposed in the end portion of the stacked body.

2. The frameless solar cell panel according to claim 1, wherein the first substrate includes a first outer surface and a first outer edge portion located on the first outer surface,
wherein the back sheet or the second substrate includes a second outer surface and a second outer edge portion located on the second outer surface,
wherein the silicone sealant member covers at least the end portion of the stacked body, the first outer edge portion of the first substrate, and the second outer edge portion of the back sheet or the second substrate, and
wherein the silicone sealant member is formed substantially in a U-shape in a cross-sectional view of the stacked body.

3. The frameless solar cell panel according to claim 1, wherein the first substrate includes a first outer surface and a first outer edge portion located on the first outer surface,
wherein the silicone sealant member covers at least the end portion of the stacked body and the first outer edge portion of the first substrate, and
wherein the silicone sealant member is formed substantially in an L-shape in a cross-sectional view of the stacked body.

4. The frameless solar cell panel according to claim 1, wherein an adhesive layer formed of butyl rubber is disposed between the silicone sealant member and the stacked body.

5. The frameless solar cell panel according to claim 1, further comprising a metallic member disposed in the end portion of the stacked body,
wherein the silicone sealant member is disposed in the end portion so as to cover the metallic member.

6. The frameless solar cell panel according to claim 1, wherein the sealing layer contains one of a silane-modified polyolefin, an ethylene-unsaturated carboxylic acid copolymer, ionomers thereof, and an ethylene-unsaturated carboxylic ester copolymer.

7. The frameless solar cell panel according to claim 1, wherein the sealing layer contains one of ethylene vinyl acetate and polyvinyl butyral.

8. A method of manufacturing a frameless solar cell panel, comprising:
preparing a stacked body that has an end portion and in which a first substrate, a power generating section, a sealing layer, and a back sheet or a second substrate are sequentially stacked;
coating the end portion of the stacked body with a silicone sealant material; and
curing the silicone sealant material.

9. The method of manufacturing a frameless solar cell panel according to claim 8, wherein the curing of the silicone sealant material is performed after the coating with the silicone sealant material is performed.

10. The method of manufacturing a frameless solar cell panel according to claim 8, wherein the curing of the silicone sealant material is performed while the coating with the silicone sealant material is being performed.

11. The method of manufacturing a frameless solar cell panel according to claim 8, wherein high-humidity air is blown to the silicone sealant material at the time of curing the silicone sealant material.

12. The method of manufacturing a frameless solar cell panel according to claim 8, wherein a metallic member is disposed in the end portion of the stacked body, and
wherein the end portion is coated with the silicone sealant material so as to cover the metallic member.

13. The method of manufacturing a frameless solar cell panel according to claim 8, wherein the sealing layer contains one of a silane-modified polyolefin, an ethylene-unsaturated carboxylic acid copolymer, ionomers thereof, and an ethylene-unsaturated carboxylic ester copolymer.

14. The method of manufacturing a frameless solar cell panel according to claim 8, wherein the sealing layer contains one of ethylene vinyl acetate and polyvinyl butyral.
